(19) United States
(12) Patent Application Publication
(10) Pub. No.: US 2026/0293197 A1
(43) Pub. Date: Sep. 24, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Hitoshi FUJIOKA, Nisshin-shi (JP)

(21) Appl. No.: 19/314,605

(22) Filed: Aug. 29, 2025

(30) Foreign Application Priority Data
Jan. 28, 2025 (JP) 2025-012131

(51) Int. Cl. H10D 30/66; H10D 62/832

(52) U.S. Cl. CPC H10D 30/668; H10D 62/8325

(57) ABSTRACT

A semiconductor substrate has an inter-trench semiconductor layer between trenches. The semiconductor substrate includes: a first semiconductor region of a first conductivity type in contact with a gate insulating film on a side surface of the trench; a second semiconductor region of a second conductivity type in contact with the gate insulating film on a side surface of the trench; a third semiconductor region of a first conductivity type in contact with the gate insulating film and the upper electrode on a side surface of the trench above the second semiconductor region; and a fourth semiconductor region of a second conductivity type having a higher second conductivity type impurity concentration than the second semiconductor region. The fourth semiconductor region is in contact with the second semiconductor region and in contact with the upper electrode on a side surface of the trench above the second semiconductor region.

### CROSS REFERENCE TO RELATED APPLICATION

This application is based on Japanese Patent Application No. 2025-012131 filed on Jan. 28, 2025, the disclosure of which is incorporated herein by reference.

### TECHNICAL FIELD

The present disclosure relates to a semiconductor device.

### BACKGROUND

In order to improve the electrical characteristics of trench gate type semiconductor device, the distance between adjacent trenches is narrowed.

### SUMMARY

According to an aspect of the present application, a semiconductor device includes: a semiconductor substrate; trenches provided on an upper surface of the semiconductor substrate; a gate insulating film covering an inner surface of each of the trenches; a gate electrode disposed in each of the trenches and insulated from the semiconductor substrate by the gate insulating film; and an interlayer insulating film disposed in each of the trenches and covering an upper surface of the gate electrode. An upper surface of the interlayer insulating film is located lower than the upper surface of the semiconductor substrate. The semiconductor device includes an upper electrode covering a side surface of the trench located higher than the upper surface of the interlayer insulating film and the upper surface of the semiconductor substrate. The semiconductor substrate has an inter-trench semiconductor layer between two adjacent trenches. The semiconductor substrate may have: a first semiconductor region of a first conductivity type in contact with the gate insulating film on a side surface of the trench; a second semiconductor region of a second conductivity type disposed in the inter-trench semiconductor layer and in contact with the gate insulating film on a side surface of the trench above the first semiconductor region; a third semiconductor region of a first conductivity type disposed in the inter-trench semiconductor layer and in contact with the gate insulating film and the upper electrode on a side surface of the trench above the second semiconductor region and separated from the first semiconductor region by the second semiconductor region; and a fourth semiconductor region of a second conductivity type disposed in the inter-trench semiconductor layer and having a higher second conductivity type impurity concentration than the second semiconductor region, in contact with the second semiconductor region from above, and in contact with the upper electrode on a side surface of the trench above the second semiconductor region.

### BRIEF DESCRIPTION OF DRAWINGS

FIG. 1 is a perspective view of a semiconductor device according to a first embodiment.

FIG. 2 is a cross-sectional view taken along a plane II in FIG. 1.

FIG. 3 is a cross-sectional view taken along a plane III in FIG. 1.

FIG. 4 is a graph showing a relationship between a width of an inter-trench semiconductor layer and a p-type impurity concentration of a body region.

FIG. 5 is a perspective view of a semiconductor device according to a second embodiment.

### DETAILED DESCRIPTION

In order to improve the electrical characteristics of trench gate type semiconductor device, the distance between adjacent trenches is narrowed. For example, a bulk channel effect can be exerted in the body region between the adjacent trenches by narrowing the distance between the adjacent trenches. In the body region where the bulk channel effect is exerted, electrons can flow even at positions distant from the gate insulating film. Therefore, electrons are less susceptible to scattering caused by the interface between the gate insulating film and the body region. As a result, the electron mobility is improved and the channel resistance is reduced. Although the bulk channel effect is used as an example to explain why it is desirable to narrow the gap between adjacent trenches, the reason for narrowing the gap between adjacent trenches is not limited to this example. This specification proposes a technique that is useful when it is desired to narrow the distance between adjacent trenches for various reasons.

In a semiconductor device, the source region and the body region are in contact with the source electrode on the upper surface of the semiconductor substrate located between adjacent trenches. Therefore, when the distance between adjacent trenches is narrowed, it becomes difficult to ensure a sufficient contact area between the source region and the source electrode, and a sufficient contact area between the body region and the source electrode. As a result, the on-resistance of the semiconductor device is increased, since the contact resistance between the source region and the source electrode and the contact resistance between the body region and the source electrode increase. This specification proposes a technique for suppressing an increase in on-resistance even when the distance between adjacent trenches is narrowed.

A semiconductor device disclosed in this specification includes: a semiconductor substrate; trenches provided on an upper surface of the semiconductor substrate; a gate insulating film covering the inner surface of each of the trenches; a gate electrode disposed in each of the trenches and insulated from the semiconductor substrate by the gate insulating film; an interlayer insulating film disposed in each of the trenches and covering an upper surface of the gate electrode, the upper surface of the interlayer insulating film being located lower than the upper surface of the semiconductor substrate; and an upper electrode covering a side surface of the trench located higher than the upper surface of the interlayer insulating film and the upper surface of the semiconductor substrate. The semiconductor substrate has an inter-trench semiconductor layer between two adjacent trenches. The semiconductor substrate has: a first semiconductor region of a first conductivity type in contact with the gate insulating film on a side surface of the trench; a second semiconductor region of a second conductivity type disposed in the inter-trench semiconductor layer and in contact with the gate insulating film on a side surface of the trench above the first semiconductor region; a third semiconductor region of a first conductivity type disposed in the inter-trench semiconductor layer and in contact with the gate insulating film and the upper electrode on a side surface of the trench above the second semiconductor region and separated from the first semiconductor region by the second semiconductor region; and a fourth semiconductor region of a second conductivity type disposed in the inter-trench semiconductor layer and having a higher second conductivity type impurity concentration than the second semiconductor region, in contact with the second semiconductor region from above, and in contact with the upper electrode on a side surface of the trench above the second semiconductor region.

In this semiconductor device, the third semiconductor region of the first conductivity type and the fourth semiconductor region of the second conductivity type are each in contact with the upper electrode on the side surface of the trench. Therefore, even if the distance between adjacent trenches is narrow, the contact area between the third semiconductor region and the upper electrode can be increased, and the contact area between the fourth semiconductor region and the upper electrode can be increased. Thus, in this semiconductor device, the contact resistance between the third and fourth semiconductor regions and the upper electrode is low, such that a low on-resistance can be achieved.

In the semiconductor device disclosed in this specification, as an example, the fourth semiconductor region may cover an upper surface of the third semiconductor region. The fourth semiconductor region may be in contact with the upper electrode on the upper surface of the semiconductor substrate.

With this configuration, a large contact area between the fourth semiconductor region and the upper electrode can be ensured, and a large area of the third semiconductor region can be ensured when the semiconductor substrate is viewed from above. Therefore, the contact resistance between the fourth semiconductor region and the upper electrode can be further reduced, and a wide region that functions as a channel can be secured.

In the semiconductor device disclosed in this specification, as an example, the semiconductor substrate may be made of a wide bandgap semiconductor. Examples of the wide bandgap semiconductor include silicon carbide, nitride semiconductor, and gallium oxide.

In the semiconductor device disclosed in this specification, the wide band gap semiconductor may be silicon carbide. When a width of the inter-trench semiconductor layer is Ws (nm) and a concentration of the second conductivity type impurity in the second semiconductor region is N (cm⁻³), a relationship of Ws<3.52×10¹¹N^{-0.526} may be satisfied.

With this configuration, the bulk channel effect can be exerted in the second semiconductor region.

In the semiconductor device disclosed in this specification, as an example, a depth from the upper surface of the semiconductor substrate to the upper surface of the interlayer insulating film may be greater than a width of the trench.

With this configuration, the contact area between the third and fourth semiconductor regions and the upper electrode on the side surface of the trench can be increased.

### First Embodiment

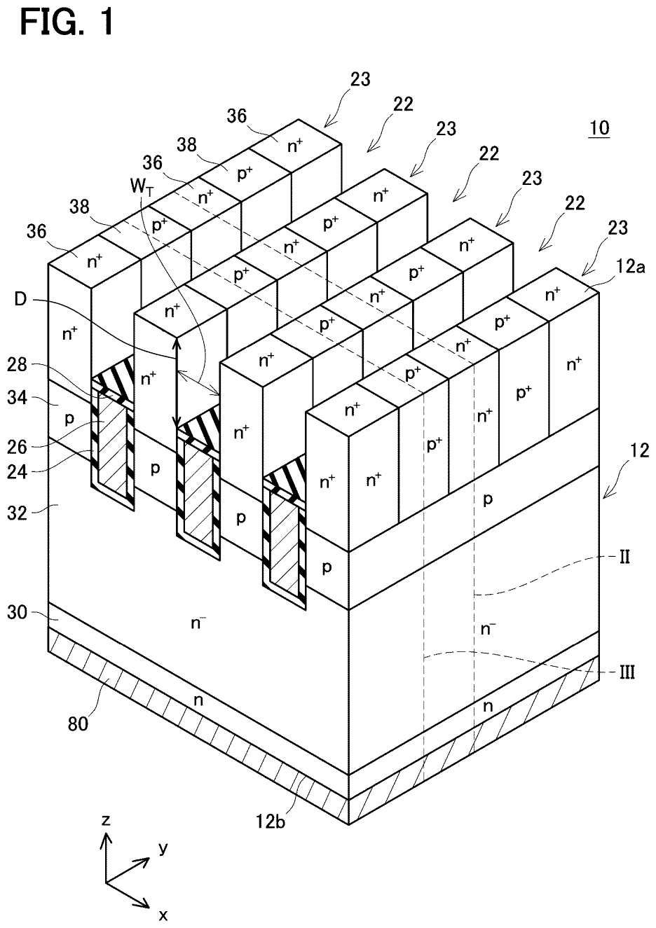

FIGS. 1 to 3 show a semiconductor device 10 according to a first embodiment. The semiconductor device 10 is a MOSFET (Metal-Oxide-Semiconductor Field-Effect Transistor). The semiconductor device 10 includes a semiconductor substrate 12. The semiconductor substrate 12 is made of silicon carbide (SiC). However, the material constituting the semiconductor substrate 12 is not limited, and may be silicon (Si) or other semiconductor materials such as other wide bandgap semiconductors. The wide bandgap semiconductor includes, for example, nitride semiconductors such as gallium nitride (GaN), and gallium oxide. In the following, a direction parallel to an upper surface 12a of the semiconductor substrate 12 is referred to as x direction, a direction parallel to the upper surface 12a and perpendicular to the x direction is referred to as y direction, and a thickness direction of the semiconductor substrate 12 is referred to as z direction.

Plural trenches 22 are disposed on the upper surface 12a of the semiconductor substrate 12. As shown in FIG. 1, the trenches 22 extend parallel to one another on the upper surface 12a. Each of the trenches 22 extends linearly in the y direction. The trenches 22 are arranged at interval in the x direction. Hereinafter, each semiconductor region between two adjacent trenches 22 will be referred to as an inter-trench semiconductor layer 23. Since the interval between the trenches 22 is narrow, the inter-trench semiconductor layer 23 has a fin shape in which the height is larger than the width. A gate insulating film 24, a gate electrode 26, and an interlayer insulating film 28 are disposed inside each of the trenches 22.

The gate insulating film 24 covers an inner surface of the trench 22. An upper end of the gate insulating film 24 is located below the upper surface 12a of the semiconductor substrate 12. In other words, the upper end of the gate insulating film 24 is located inside the trench 22.

The gate electrode 26 is disposed inside the trench 22. The gate electrode 26 is insulated from the semiconductor substrate 12 by the gate insulating film 24.

The interlayer insulating film 28 covers an upper surface of the gate electrode 26. The upper surface of the interlayer insulating film 28 is located below the upper surface 12a of the semiconductor substrate 12. That is, the upper surface of the interlayer insulating film 28 is located inside the trench 22. In this embodiment, the depth D from the upper surface 12a of the semiconductor substrate 12 to the upper surface of the interlayer insulating film 28 is greater than the width W_{T} of the trench 22.

A drain electrode 80 is arranged at a lower surface 12b of the semiconductor substrate 12. The drain electrode 80 is in contact with substantially the entire lower surface 12b of the semiconductor substrate 12.

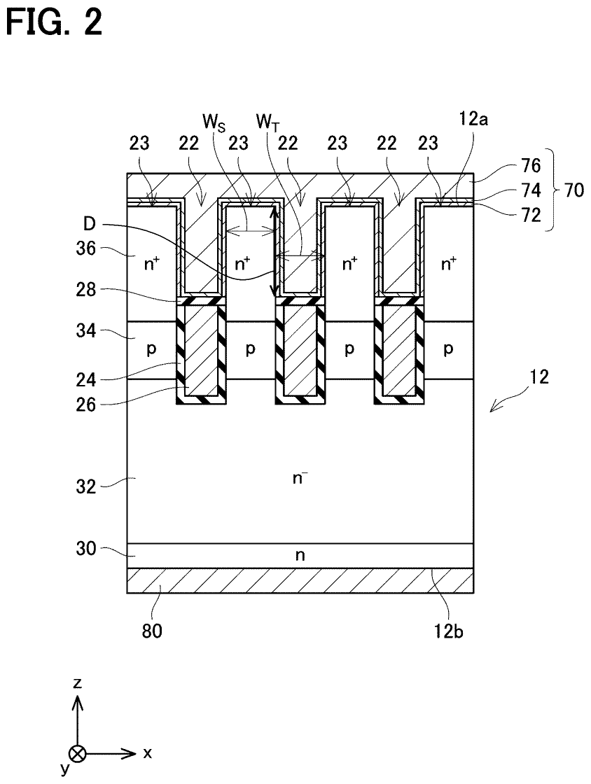

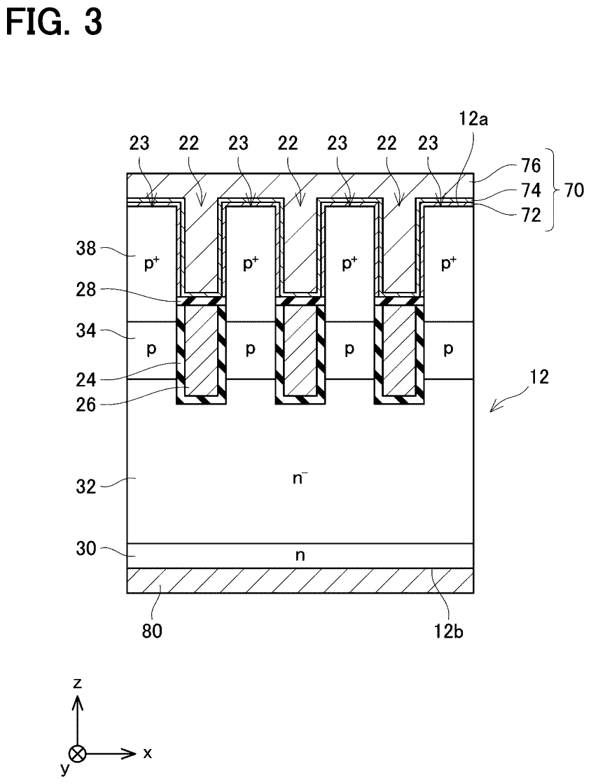

As illustrated in FIGS. 2 and 3, a source electrode 70 is disposed on the upper surface 12a of the semiconductor substrate 12. The source electrode 70 is disposed across the inside of the trench 22 from the upper surface 12a. The source electrode 70 covers the upper surface 12a of the semiconductor substrate 12, the side surface of the trench 22 located above the interlayer insulating film 28, and the upper surface of the interlayer insulating film 28. The source electrode 70 is insulated from the gate electrode 26 by the interlayer insulating film 28. The source electrode 70 includes a silicide layer 72, a barrier metal layer 74, and an aluminum layer 76. The source electrode 70 is an example of an upper electrode.

The silicide layer 72 extends from the upper surface 12a of the semiconductor substrate 12 into the trench 22. The silicide layer 72 extends to a position in contact with the upper surface of the interlayer insulating film 28. The silicide layer 72 covers the upper surface 12a of the semiconductor substrate 12 and the side surface of the trench 22 located above the upper surface of the interlayer insulating film 28. The silicide layer 72 is made of, for example, a compound of nickel and silicon.

The barrier metal layer 74 extends from the silicide layer 72 into the trench 22. The barrier metal layer 74 covers the surface of the silicide layer 72 and the upper surface of the interlayer insulating film 28. The barrier metal layer 74 is made of, for example, a metal containing titanium (such as titanium alone or an alloy of titanium and aluminum).

The aluminum layer 76 extends from an upper side of the upper surface 12a of the semiconductor substrate 12 to a location inside the trench 22. The aluminum layer 76 covers the surface of the barrier metal layer 74. The aluminum layer 76 fills the inside of the trench 22.

As shown in FIGS. 1 to 3, a drain region 30, a drift region 32, a body region 34, plural source regions 36, and plural contact regions 38 are provided inside the semiconductor substrate 12.

The drain region 30 is an n-type region. The drain region 30 is provided at a position exposed on the lower surface 12b of the semiconductor substrate 12. The drain region 30 is in ohmic contact with the drain electrode 80.

The drift region 32 is an n-type region. The drift region 32 is in contact with the drain region 30 from above. The drift region 32 has a lower n-type impurity concentration than the drain region 30. The drift region 32 is distributed from a region below each trench 22 across each inter-trench semiconductor layer 23. The drift region 32 is in contact with the gate insulating film 24 at the bottom surface of the trench 22 and the side surface of the lower end part of the trench 22. The drift region 32 is an example of a first semiconductor region.

The body region 34 is a p-type region. The body region 34 is disposed in each inter-trench semiconductor layer 23. The body region 34 is in contact with the drift region 32 from above. The body region 34 is distributed over the entire upper side of the drift region 32. The body region 34 is in contact with the gate insulating film 24 on the side surface of the trench 22 above the drift region 32. The upper end of the body region 34 is located below the upper end of the gate electrode 26. The body region 34 is an example of a second semiconductor region.

Each of the source regions 36 is an n-type region. As shown in FIGS. 1 and 2, the source region 36 is disposed in each inter-trench semiconductor layer 23. As shown in FIG. 1, the source regions 36 are disposed in the inter-trench semiconductor layer 23, and arranged at interval in the y direction. Each of the source regions 36 is in contact with the body region 34 from above. Each source region 36 is separated from the drift region 32 by the body region 34. As shown in FIG. 2, each source region 36 is in contact with the gate insulating film 24 on the side surface of the trench 22 above the body region 34. Each source region 36 extends within each inter-trench semiconductor layer 23 from a position in contact with one trench 22 to a position in contact with the other trench 22, and also extends from the upper surface of the body region 34 to a position exposed on the upper surface 12a of the semiconductor substrate 12. Each source region 36 is in ohmic contact with the source electrode 70 on the side surface of the trench 22 and on the upper surface 12a of the semiconductor substrate 12. More specifically, each source region 36 makes ohmic contact with the silicide layer 72. The source region 36 is an example of a third semiconductor region.

Each of the contact regions 38 is a p-type region. As shown in FIGS. 1 and 3, the contact region 38 is disposed in each inter-trench semiconductor layer 23. As shown in FIG. 1, in the inter-trench semiconductor layer 23, the contact regions 38 are arranged at interval in the y direction. The source regions 36 and the contact regions 38 are arranged alternately in the y direction. Each contact region 38 is in contact with the body region 34 from above. Each of the contact regions 38 has a p-type impurity concentration higher than that of the body region 34. As shown in FIG. 3, each contact region 38 is in contact with the gate insulating film 24 on the side surface of the trench 22 above the body region 34. Each contact region 38 extends within each inter-trench semiconductor layer 23 from a position in contact with one trench 22 to a position in contact with the other trench 22, and also extends from the upper surface of the body region 34 to a position exposed on the upper surface 12a of the semiconductor substrate 12. Each contact region 38 is in ohmic contact with the source electrode 70 on the side surface of the trench 22 and on the upper surface 12a of the semiconductor substrate 12. More specifically, each contact region 38 makes ohmic contact with the silicide layer 72. The contact region 38 is an example of a fourth semiconductor region.

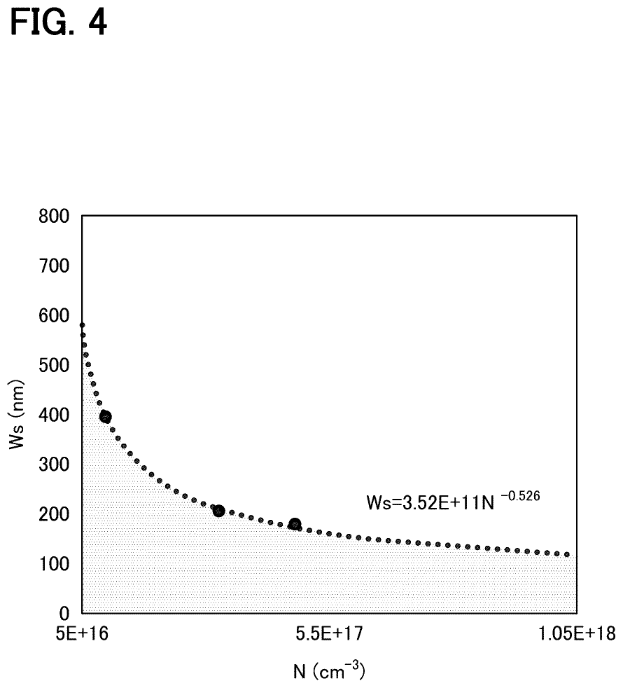

FIG. 4 is a graph showing a relationship between the width Ws (nm) of the inter-trench semiconductor layer 23 in the x direction and the p-type impurity concentration N (cm⁻³) of the body region 34. As shown by hatching in FIG. 4, in this embodiment, the width Ws of the inter-trench semiconductor layer 23 and the p-type impurity concentration N of the body region 34 are set so that the relationship Ws<3.52×10¹¹N^{-0.526} is satisfied.

Next, the operation of the semiconductor device 10 will be described. When the semiconductor device 10 is in use, the semiconductor device 10, a load (for example, a motor), and a power supply are connected in series. A power supply voltage is applied to the series circuit of the semiconductor device 10 and the load. The power supply voltage is applied in a direction in which the drain electrode 80 has a higher potential than the source electrode 70. As described above, in this embodiment, the width Ws of the inter-trench semiconductor layer 23 and the p-type impurity concentration N of the body region 34 are set so that the relationship of Ws<3.52×10¹¹N^{-0.526} is satisfied. In other words, the width Ws of the inter-trench semiconductor layer 23 (i.e., the width of the body region 34) is sufficiently narrow compared to the height of the p-type impurity concentration N of the body region 34. Therefore, when a potential higher than the gate threshold is applied to the gate electrode 26, a channel is formed not only in the vicinity of the gate insulating film 24 but also in the body region 34 away from the gate insulating film 24. In other words, the width of the channel formed near the gate insulating film 24 on both sides of each body region 34 becomes wider than half the width of the body region 34. The channels are coupled together within the body region 34, to form a channel throughout the entire body region 34. In the semiconductor device 10, the source region 36 and the drift region 32 are connected via such a bulk channel. As a result, electrons flow from the source electrode 70 to the drain electrode 80 via the source region 36, the bulk channel, the drift region 32, and the drain region 30, turning on the semiconductor device 10. When the potential of the gate electrode 26 is lowered to a potential lower than the gate threshold voltage, the channel formed in the body region 34 disappears, and the semiconductor device 10 is turned off.

As described above, in this semiconductor device 10, the source region 36 and the contact region 38 are in ohmic contact with the source electrode 70 not only on the upper surface 12a of the semiconductor substrate 12 but also on the side surface of the trench 22. Therefore, the contact area between each of the source region 36 and the contact region 38 and the source electrode 70 is larger, compared with a configuration in which the source region 36 and the contact region 38 are in contact with the source electrode only on the upper surface of the semiconductor substrate. Therefore, the contact resistance between the source region 36 and the contact region 38 and the source electrode 70 is low, and the semiconductor device 10 can achieve a low on-resistance.

Furthermore, in the semiconductor device 10 of this embodiment, the width Ws of the inter-trench semiconductor layer 23 is narrow enough to allow a bulk channel to be formed in the body region 34. In the semiconductor device 10, since the width Ws is narrow, it is difficult to ensure a sufficient contact area between the source region 36 and the contact region 38 and the source electrode 70 on the upper surface 12a of the semiconductor substrate 12. However, as described above, in this embodiment, the contact area with the source electrode 70 can be further secured on the side surface of the trench 22, and therefore the technology disclosed in this specification can be said to be useful when it is desired to narrow the width of the inter-trench semiconductor layer 23. As a specific value of the width Ws of the inter-trench semiconductor layer 23 disclosed in this specification, the width Ws may be, for example, 600 nm or less, or 400 nm or less.

In the semiconductor device 10 of this embodiment, the semiconductor substrate 12 is made of silicon carbide, which is a wide bandgap semiconductor. In the semiconductor substrate 12 made of silicon carbide, the mobility of electrons is particularly low near the interface with the gate insulating film 24. For this reason, the technology disclosed in this specification is particularly useful when using the semiconductor substrate 12 made of a semiconductor material, to exhibit a bulk channel effect.

In the semiconductor device 10 of this embodiment, the depth D from the upper surface 12a of the semiconductor substrate 12 to the upper surface of the interlayer insulating film 28 is greater than the width W_{T} of the trench 22. This makes it possible to ensure a larger contact area between the source region 36 and the contact region 38 and the source electrode 70.

### Second Embodiment

In the semiconductor device 10 of the second embodiment, the configurations of the source region 136 and the contact region 138 are different from those of the first embodiment. The other configurations are the same as those in the first embodiment.

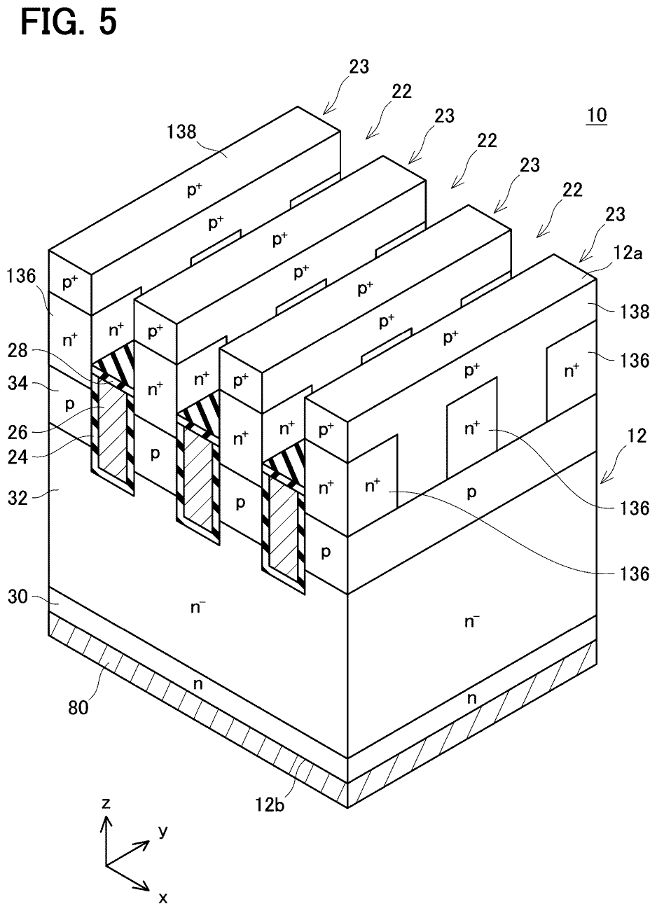

As shown in FIG. 5, in the semiconductor device 10 of the second embodiment, the contact region 138 covers the upper surface of the source region 136. In the inter-trench semiconductor layer 23, the contact region 138 is exposed over substantially the entire upper surface 12a of the semiconductor substrate 12. In other words, in the semiconductor device 10 of the second embodiment, the source region 136 in the inter-trench semiconductor layer 23 is not exposed to the upper surface 12a of the semiconductor substrate 12. On the upper surface 12a of the semiconductor substrate 12, only the contact region 138 is in ohmic contact with the source electrode 70. In the range where the source region 136 and the contact region 138 overlap in the z direction, the lower end of the contact region 138 is located above the upper end of the interlayer insulating film 28. That is, also in the second embodiment, the source region 136 and the contact region 138 are in ohmic contact with the source electrode 70 on the side surface of the trench 22. It can be said that the semiconductor device 10 of the second embodiment has a configuration in which the region located on the upper surface of the source region 36, in the configuration of the first embodiment, is replaced with the contact region 38.

In the semiconductor device 10 of the second embodiment, the contact region 138 is exposed over substantially the entire upper surface 12a of the semiconductor substrate 12, so that a larger contact area between the contact region 138 and the source electrode 70 can be ensured. Moreover, when the semiconductor substrate 12 is viewed from above, the area of the source region 136 is equal to that of the first embodiment. Therefore, in the second embodiment, the contact resistance between the contact region 138 and the source electrode 70 can be further reduced, and a wide region that functions as a channel can be secured. In the second embodiment, the contact area between the source region 136 and the source electrode 70 is smaller than that in the first embodiment. However, for example, by narrowing the distance between adjacent source regions 136 in the y direction (i.e., narrowing the width of the contact region 138 located between adjacent source regions 136 in the y direction), the contact area between the source region 136 and the source electrode 70 can be adjusted appropriately.

In the above embodiment, the relationship Ws<3.52×10¹¹N^{-0.526} is established between the width Ws (nm) of the inter-trench semiconductor layer 23 in the x direction and the p-type impurity concentration N (cm⁻³) of the body region 34, but this relationship does not have to be satisfied. That is, the bulk channel effect may not occur in the body region 34. As described above, the technology disclosed in this specification is useful when it is desired to narrow the spacing between adjacent trenches 22 for various reasons, and the technology disclosed in this specification can also be appropriately adopted in semiconductor devices in which the bulk channel effect does not occur.

Furthermore, the relationship between the depth D from the upper surface 12a of the semiconductor substrate 12 to the upper surface of the interlayer insulating film 28 and the width W_{T} of the trench 22 is not particularly limited. The depth D may not be greater than the width W_{T}.

Furthermore, in the above embodiments, the semiconductor device 10 is a MOSFET, but the semiconductor device 10 may be, for example, an IGBT (Insulated Gate Bipolar Transistor).

Although specific examples of the present disclosure have been described in detail above, these are merely examples and do not limit the scope of the claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A semiconductor device comprising:
a semiconductor substrate;
a plurality of trenches provided on an upper surface of the semiconductor substrate;
a gate insulating film covering an inner surface of each of the plurality of trenches;
a gate electrode disposed in each of the plurality of trenches and insulated from the semiconductor substrate by the gate insulating film;
an interlayer insulating film disposed in each of the plurality of trenches to cover an upper surface of the gate electrode, an upper surface of the interlayer insulating film being located lower than the upper surface of the semiconductor substrate; and
an upper electrode covering a side surface of the trench located above the upper surface of the interlayer insulating film and the upper surface of the semiconductor substrate, wherein
the semiconductor substrate has an inter-trench semiconductor layer interposed between two of the trenches adjacent to each other, and
the semiconductor substrate includes:
a first semiconductor region of a first conductivity type in contact with the gate insulating film on a side surface of the trench;
a second semiconductor region of a second conductivity type that is disposed in the inter-trench semiconductor layer and that is in contact with the gate insulating film on a side surface of the trench above the first semiconductor region;
a third semiconductor region of a first conductivity type that is disposed in the inter-trench semiconductor layer and that is in contact with the gate insulating film and the upper electrode on a side surface of the trench above the second semiconductor region, the third semiconductor region being separated from the first semiconductor region by the second semiconductor region; and
a fourth semiconductor region of a second conductivity type that is disposed in the inter-trench semiconductor layer and having a higher second conductivity type impurity concentration than the second semiconductor region, the fourth semiconductor region being in contact with the second semiconductor region from above and in contact with the upper electrode on a side surface of the trench above the second semiconductor region.

2. The semiconductor device according to claim 1, wherein
the fourth semiconductor region covers an upper surface of the third semiconductor region, and
the fourth semiconductor region is in contact with the upper electrode on the upper surface of the semiconductor substrate.

3. The semiconductor device according to claim 1, wherein the semiconductor substrate is made of a wide bandgap semiconductor.

4. The semiconductor device according to claim 3, wherein
the wide bandgap semiconductor is silicon carbide, and
a relationship of Ws<3.52×10¹¹N^{-0.526} is satisfied when a width of the inter-trench semiconductor layer is Ws (nm) and a second conductivity type impurity concentration of the second semiconductor region is N (cm⁻³).

5. The semiconductor device according to claim 1, wherein a depth from the upper surface of the semiconductor substrate to the upper surface of the interlayer insulating film is greater than a width of the trench.
